(19) United States
(12) Patent Application Publication
(10) Pub. No.: US 2002/0146856 A1
(43) Pub. Date: Oct. 10, 2002

(54) Electrode, semiconductor device and methods for making them

(76) Inventor: Etsuo Morita, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/118,097

(22) Filed: Apr. 8, 2002

Related U.S. Application Data
(62) Division of application No. 09/360,624, filed on Jul. 26, 1999.

(30) Foreign Application Priority Data
Jul. 30, 1998 (JP) P10-215821

(51) Int. Cl. H01L 21/00; H01L 21/336; H01L 21/265

(52) U.S. Cl. 438/46; 438/285; 438/518

(57) ABSTRACT

In a semiconductor device such as GaN semiconductor laser having an electrode formed on a nitride III-V compound semiconductor layer containing at least Ga, such as GaN layer, at least a part of the electrode in contact with the nitride III-V compound semiconductor layer is made of a γ-GaNi alloy or a γ′-GaNi alloy. The electrode is made by first stacking the γ-GaNi alloy layer or γ′-GaNi alloy layer, or its component elements, on the nitride III-V compound semiconductor layer, and then annealing it at a temperature not lower than 680° C., or by stacking any of them on the nitride-compound III-V compound semiconductor layer heated to a temperature not lower than 680° C. At least a part of the electrode in contact with the nitride III-V compound semiconductor layer may be made of an alloy of Ga and at least one kind of element selected from the group consisting of Pt, Ag, Pd, Mg, Hf, Al, Cr, Ti, Mo, W, Zr, Si and Ge.

### BACKGROUND OF THE INVENTION

1. Field of the Invention

This invention relates to an electrode and a method for making same, and also to a semiconductor device and its manufacturing method, particularly suitable for application to semiconductor lasers, light emitting diodes or electron transport devices which use nitride III-V compound semiconductors like GaN.

2. Description of the Related Art

As light emitting elements for light from green or blue to ultraviolet bands, there have been developed semiconductor lasers, light emitting diodes, and so on, which use nitride III-V compound semiconductors represented by GaN, containing one or more of group III elements such as Al, Ga and In, and one or more of group V elements at least including N. Among them, light emitting diodes have already been brought into practical use. Regarding semiconductor lasers, continuous oscillation at room temperatures has already been realized, and efforts are currently paid to elongating the lifetime.

In any of these light emitting elements using nitride III-V compound semiconductors, its p-side electrode and n-side electrode must be brought into ohmic contact with a p-type layer and an n-type layer, respectively. In this case, to realize a light emitting element with a high performance, for example, in luminance, it is indispensable to ensure ohmic contact of the p-side electrode and the n-side electrode under a low resistance.

In conventional elements, p-side electrodes were made of Au/Ni (Japanese-Patent Laid-Open Publication No. hei 5-291621) or Au/Pt/Ni, for example. Beside them, another conventional proposal used Mg or alloys of Mg as a material of p-side electrodes to obtain p-side electrode having a more excellent ohmic contact property (Japanese Patent Laid-Open Publication No. hei 8-64871).

However, these conventional materials of p-side electrodes make the ohmic contact resistance of the p-side electrode much higher than the ohmic contact resistance of the n-side electrode, and it has been a bar to reducing the drive voltage or power consumption of light emitting elements using nitride III-V compound semiconductors. Since it also adversely affects the lifetime and reliability of elements, its solution is an immediate need.

On the other hand, there is a recent report which teaches that good ohmic contact properties with a low contact resistance can be obtained by stacking a Au/Ni layer as an electrode material on a p-type GaN layer by beam evaporation and thereafter annealing it at 600 through 700° C. (J. Appl. Phys., Vol. 83, No. 6, 3172(1998)). This explains that the existence of GaNi alloys and GaAu alloys, such as Ga₄Ni₃, Ga₃Ni₂, GaAu and GaAu₂, for example, along the metal-semiconductor interface leads to a good ohmic contact.

However, according to the Inventor's researches, the electrode structure with the existence of GaNi alloys and GaAu alloys such as Ga₄Ni₃, Ga₃Ni₂, GaAu and GaAu₂, for example, along the metal-semiconductor interface cannot be considered to be an optimum structure, and it may rather invite instability caused especially by co-existence of various kinds of GaNi alloys and GaAu alloys.

### OBJECTS AND SUMMARY OF THE INVENTION

It is therefore an object of the invention to provide a highly stable electrode reduced in resistance and improved in adhesion at its ohmic contact with a nitride III-V compound semiconductor layer, and a method for making same, a semiconductor device using such electrodes, and a method for manufacturing the semiconductor device.

The Inventor made various experiments and researches to overcome the problems the conventional techniques involved, and has come to realize that it is effective to make γ-GaNi alloys or γ′-GaNi alloys, instead of Ga₄Ni₃, Ga₃Ni₂, GaAu and GaAu₂, for example, along the metal-semiconductor interface to bring the electrode into ohmic contact into a nitride III-V compound semiconductor layer containing Ga, such as GaN layer. This is probably because γ-GaNi alloys or γ′-GaNi alloys existing along the electrode-semiconductor interface behave as intermediaries and help to make continues bonding between the nitride compound III-V compound semiconductor layer and the electrode, which must facilitate movements of carriers and flow of a current through the electrode-semiconductor interface.

Through researches, the Inventor has also come to realize that the use of alloys of Ga with Pt, Ag, Pd, Mg, Hf, Al, Cr, Ti, Mo, W, Zr, Si, Ge, or the like, is effective as alloys to be made along the electrode-semiconductor interface. There are various kinds of such alloys as shown later, and any optimum ones can be used depending on the purpose.

The Invention has been made on the basis of the above-mentioned researches by the Inventor.

According to the first aspect of the invention, there is provided an electrode on a nitride III-V compound semiconductor layer containing at least Ga, comprising:

at least a part of the electrode in contact with the nitride III-V compound semiconductor layer being made of a γ-GaNi alloy or a γ′-GaNi alloy.

According to the second aspect of the invention, there is provided an electrode on a nitride III-V compound semiconductor layer containing at least Ga, characterized in:

being made by first stacking at least a γ-GaNi alloy or a γ′-GaNi alloy on the nitride III-V compound semiconductor layer, and next annealing it at a temperature not lower than 680° C.

In the second aspect of the invention, the electrode may be made by sequentially stacking the γ-GaNi alloy or the γ′-GaNi alloy, Pt and Au on the nitride III-V compound semiconductor layer, and next annealing them at a temperature not lower than 680° C.

According to the third aspect of the invention, there is provided an electrode on a nitride III-V compound semiconductor layer containing at least Ga, characterized in:

being made by stacking at least a γ-GaNi alloy or a γ′-GaNi alloy on the nitride III-V compound semiconductor layer heated to a temperature not lower than 680° C.

In the third aspect of the invention, the electrode may be made by sequentially stacking the γ-GaNi alloy or the γ′-GaNi alloy, Pt and Au on the nitride III-V compound semiconductor layer heated to a temperature not lower than 680° C.

According to the fourth aspect of the invention, there is provided an electrode on a nitride III-V compound semiconductor layer containing at least Ga, characterized in:

being made by first stacking at least Ga, or a first compound containing Ga, and Ni, or a second compound containing Ni, on the nitride III-V compound semiconductor layer, and next annealing them at a temperature not lower than 680° C.

According to the fifth aspect of the invention, there is provided an electrode on a nitride III-V compound semiconductor layer containing at least Ga, characterized in:

being made by first sequentially stacking Ni, Pt and Au, and next annealing them at a temperature not lower than 680° C.

According to the sixth aspect of the invention, there is provided a method for making an electrode on a nitride III-V compound semiconductor layer containing at least Ga, comprising:

stacking at least a γ-GaNi alloy or a γ′-GaNi alloy on the nitride III-V compound semiconductor layer.

According to the seventh aspect of the invention, there is provided a method for making an electrode on a nitride III-V compound semiconductor layer containing at least Ga, comprising:

first stacking at least a γ-GaNi alloy or a γ′-GaNi alloy on the nitride III-V compound semiconductor layer, and next annealing it at a temperature not lower than 680° C.

In the seventh aspect of the invention, the electrode may be made by sequentially stacking the γ-GaNi alloy or the γ′-GaNi alloy on the nitride III-V compound semiconductor layer, and by next annealing it at a temperature not lower then 680° C.

According to the eighth aspect of the invention, there is provided a method for making an electrode on a nitride III-V compound semiconductor layer containing at least Ga, comprising:

stacking at least a γ-GaNi alloy or a γ′-GaNi alloy on the nitride III-V compound semiconductor layer heated to a temperature not lower than 680° C.

In the eighth aspect of the invention, the electrode may be made by sequentially stacking the γ-GaNi alloy or γ′-GaNi alloy, Pt and Au on the nitride III-V compound semiconductor layer heated to a temperature not lower than 680° C.

According to the ninth aspect of the invention, there is provided a method for making an electrode on a nitride III-V compound semiconductor layer containing at least Ga, comprising:

first stacking at least Ga, or a first compound containing Ga, and Ni, or a second compound containing Ni, on the nitride III-V compound semiconductor layer, and next annealing them at a temperature not lower than 680° C.

According to the tenth aspect of the invention, there is provided a method for making an electrode on a nitride III-V compound semiconductor layer containing at least Ga, comprising:

first sequentially stacking Ni, Pt and Au, and next annealing them at a temperature not lower than 680° C.

According to the eleventh aspect of the invention, there is provided a semiconductor device including an electrode on a nitride III-V compound semiconductor layer containing at least Ga, comprising:

at least a part of the electrode in contact with the nitride III-V compound semiconductor layer being made of a γ-GaNi alloy or a γ′-GaNi alloy.

According to the twelfth aspect of the invention, there is provided a semiconductor device including an electrode on a nitride III-V compound semiconductor layer containing at least Ga, comprising:

the electrode being made by first stacking at least a γ-GaNi alloy or a γ′-GaNi alloy on the nitride III-V compound semiconductor layer, and next annealing it at a temperature not lower than 680° C.

In the twelfth aspect of the invention, the electrode may be made by sequentially stacking the γ-GaNi alloy or the γ′-GaNi alloy, Pt and Au on the nitride III-V compound semiconductor layer, and next annealing them at a temperature not lower than 680° C.

According too the thirteenth aspect of the invention, there is provided a semiconductor device including an electrode on a nitride III-V compound semiconductor layer containing at least Ga, comprising:

the electrode being made by stacking at least a γ-GaNi alloy or a γ′-GaNi alloy on the nitride III-V compound semiconductor layer heated to a temperature not lower than 680° C.

In the thirteenth aspect of the invention, the electrode may be made by sequentially stacking the γ-GaNi alloy or γ′-GaNi alloy, Pt and Au on the nitride III-V compound semiconductor layer heated to a temperature not lower than 680° C.

According to the fourteenth aspect of the invention, there is provided a semiconductor device including an electrode on a nitride III-V compound semiconductor layer containing at least Ga, comprising:

the electrode being made by first stacking at least Ga, or a first compound containing Ga, and Ni, or a second compound containing Ni, on the nitride III-V compound semiconductor layer, and next annealing them at a temperature not lower than 680° C.

According to the fifteenth aspect of the invention, there is provided a semiconductor device including an electrode on a nitride III-V compound semiconductor layer containing at least Ga, comprising:

the electrode being made by first sequentially stacking Ni, Pt and Au, and next annealing them at a temperature not lower than 680° C.

According to the sixteenth aspect of the invention, there is provided a method for manufacturing a semiconductor device including an electrode on a nitride III-V compound semiconductor layer containing at least Ga, comprising:

the electrode being made by stacking at least a γ-GaNi alloy or a γ′-GaNi alloy on the nitride III-V compound semiconductor layer.

According to the seventeenth aspect of the invention, there is provided a method for manufacturing a semiconductor device including an electrode on a nitride III-V compound semiconductor layer containing at least Ga, comprising:

the electrode being made by first stacking at least a γ-GaNi alloy or a γ′-GaNi alloy on the nitride III-V compound semiconductor layer, and next annealing it at a temperature not lower than 680° C.

In the seventeenth aspect of the invention, the electrode may be made by sequentially stacking the γ-GaNi alloy or γ′-GaNi alloy on the nitride III-V compound semiconductor layer, and it is next annealed at a temperature not lower then 680° C.

According to the eighteenth aspect of the invention, there is provided a method for manufacturing a semiconductor device including an electrode on a nitride III-V compound semiconductor layer containing at least Ga, comprising:

the electrode being made by stacking at least a γ-GaNi alloy or a γ′-GaNi alloy on the nitride III-V compound semiconductor layer heated to a temperature not lower than 680° C.

In the eighteenth aspect of the invention, the electrode may be made by sequentially stacking the γ-GaNi alloy or γ′-GaNi alloy, Pt and Au on the nitride III-V compound semiconductor layer heated to a temperature not lower than 680° C.

According to the nineteenth aspect of the invention, there is provided a method for manufacturing a semiconductor device including an electrode on a nitride III-V compound semiconductor layer containing at least Ga, comprising:

the electrode being made by first stacking at least Ga, or a first compound containing Ga, and Ni, or a second compound containing Ni, on the nitride III-V compound semiconductor layer, and next annealing them at a temperature not lower than 680° C.

According to the twentieth aspect of the invention, there is provided a method for manufacturing a semiconductor device including an electrode on a nitride III-V compound semiconductor layer containing at least Ga, comprising:

the electrode being made by first sequentially stacking Ni, Pt and Au, and next annealing them at a temperature not lower than 680° C.

In the first to fourth, sixth to ninth, eleventh to fourteenth and sixteenth to nineteenth aspects of the invention, a metal for reducing the resistance of the electrode, which may be Au, for example, is typically provided to overlie. In this case, Pt is preferably stacked as a base layer of Au in order to prevent interaction of overlying Au with the underlying γ-GaNi alloys or γ′-GaNi alloys, or materials for making them.

In the first to twentieth aspects of the invention, the temperature 680° C. as the annealing temperature or heating temperature corresponds to the temperature for making γ-GaNi alloys or γ′-GaNi alloys. These γ-GaNi alloys or γ′-GaNi alloys are GaNi alloys each containing Ga by 36 atomic % and Ni by 64 atomic %. A difference between them lies in that γ-GaNi alloys have high-temperature phases whereas γ′-GaNi alloys have low-temperature phases.

In the first to twentieth aspects of the invention, the annealing temperature or heating temperature may be basically not lower than 680° C. which is the temperature for making γ-GaNi alloys or γ′-GaNi alloys. However, it is known to the Inventor through his experiences that, if the temperature is excessively high, it becomes difficult to obtain stable ohmic contact. Therefore, it is chosen below 730° C., for example.

According to the 21st aspect of the invention, there is provided an electrode on a nitride III-V compound semiconductor layer containing at least Ga, comprising:

at least a part of the electrode in contact with the nitride III-V compound semiconductor layer being made of an alloy of Ga and at least one kind of element selected from the group consisting of Pt, Ag, Pd, Mg, Hf, Al, Cr, Ti, Mo, W, Zr, Si and Ge.

According to the 22nd aspect of the invention, there is provided an electrode on a nitride III-V compound semiconductor layer containing at least Ga, characterized in:

being made by first stacking an alloy of Ga and at least one kind of element selected from the group consisting of Pt, Ag, Pd, Mg, Hf, Al, Cr, Ti, Mo, W, Zr, Si and Ge, and next annealing it at a temperature not lower than a temperature required for making the alloy.

According to the 23rd aspect of the invention, there is provided an electrode on a nitride III-V compound semiconductor layer containing at least Ga, characterized in:

being made by sequentially stacking an alloy of Ga and at least one kind of element selected from the group consisting of Pt, Ag, Pd, Mg, Hf, Al, Cr, Ti, Mo, W, Zr, Si and Ge on the nitride III-V compound semiconductor layer heated to a temperature not lower than a temperature required for making the alloy.

According to the 24th aspect of the invention, there is provided an electrode on a nitride III-V compound semiconductor layer containing at least Ga, characterized in:

being made by stacking at least Ga or a first compound containing Ga, and at least one kind of element selected from the group consisting of Pt, Ag, Pd, Mg, Hf, Al, Cr, Ti, Mo, W, Zr, Si and Ge or a second compound containing the at least one kind of element on the nitride III-V compound semiconductor layer, and next annealing them at a temperature not lower than a temperature required for making an alloy of Ga and the at least one kind of element.

According to the 25th aspect of the invention, there is provided a method for making an electrode on a nitride III-V compound semiconductor layer containing at least Ga, comprising:

stacking at least an alloy of Ga and at least one kind of element selected from the group consisting of Pt, Ag, Pd, Mg, Hf, Al, Cr, Ti, Mo, W, Zr, Si and Ge.

According to the 26th aspect of the invention, there is provided a method for making an electrode on a nitride III-V compound semiconductor layer containing at least Ga, comprising:

first stacking at least an alloy of Ga and at least one kind of element selected from the group consisting of Pt, Ag, Pd, Mg, Hf, Al, Cr, Ti, Mo, W, Zr, Si and Ge, and next annealing it at a temperature not lower than a temperature required for making the alloy.

According to the 27th aspect of the invention, there is provided a method for making an electrode on a nitride III-V compound semiconductor layer containing at least Ga, comprising:

sequentially stacking an alloy of Ga and at least one kind of element selected from the group consisting of Pt, Ag, Pd, Mg, Hf, Al, Cr, Ti, Mo, W, Zr, Si and Ge on the nitride III-V compound semiconductor layer heated to a temperature not lower than a temperature required for making the alloy.

According to the 28th aspect of the invention, there is provided a method for making an electrode on a nitride III-V compound semiconductor layer containing at least Ga, comprising:

stacking at least Ga or a first compound containing Ga, and at least one kind of element selected from the group consisting of Pt, Ag, Pd, Mg, Hf, Al, Cr, Ti, Mo, W, Zr, Si and Ge or a second compound containing the at least one kind of element on the nitride III-V compound semiconductor layer, and next annealing them at a temperature not lower than a temperature required for making an alloy of Ga and the at least one kind of element.

According to the 29th aspect of the invention, there is provided a method for making an electrode on a nitride III-V compound semiconductor layer containing at least Ga, comprising:

stacking at least Ga or a first compound containing Ga, and at least one kind of element selected from the group consisting of Pt, Ag, Pd, Mg, Hf, Al, Cr, Ti, Mo, W, Zr, Si and Ge or a second compound containing the at least one kind of element on the nitride III-V compound semiconductor layer heated to a temperature not lower than a temperature required for making an alloy of Ga and the at least one kind of element.

According to the 30th aspect of the invention, there is provided a semiconductor device including an electrode on a nitride III-V compound semiconductor layer containing at least Ga, comprising:

at least a part of the electrode in contact with the nitride III-V compound semiconductor layer being made of an alloy of Ga and at least one kind of element selected from the group consisting of Pt, Ag, Pd, Mg, Hf, Al, Cr, Ti, Mo, W, Zr, Si and Ge.

According to the 31st aspect of the invention, there is provided a semiconductor device including an electrode on a nitride III-V compound semiconductor layer containing at least Ga, comprising:

the electrode being made by first stacking at least an alloy of Ga and at least one kind of element selected from the group consisting of Pt, Ag, Pd, Mg, Hf, Al, Cr, Ti, Mo, W, Zr, Si and Ge, and then annealing it at a temperature not lower than a temperature required for making an alloy of Ga and the at least one kind of element.

According to the 32nd aspect of the invention, there is provided a semiconductor device including an electrode on a nitride III-V compound semiconductor layer containing at least Ga, comprising:

the electrode being made by stacking at least an alloy of Ga and at least one kind of element selected from the group consisting of Pt, Ag, Pd, Mg, Hf, Al, Cr, Ti, Mo, W, Zr, Si and Ge on the nitride III-V compound semiconductor layer heated to a temperature not lower than a temperature required for making the alloy.

According to the 33rd aspect of the invention, there is provided a semiconductor device including an electrode on a nitride III-V compound semiconductor layer containing at least Ga, comprising:

stacking at least Ga or a first compound containing Ga, and at least one kind of element selected from the group consisting of Pt, Ag, Pd,. Mg, Hf, Al, Cr, Ti, Mo, W, Zr, Si and Ge or a second compound containing the at least one kind of element on the nitride III-V compound semiconductor layer, and then annealing it at a temperature not lower than a temperature required for making an alloy of Ga and the at least one kind of element.

According to the 34th aspect of the invention, there is provided a method for manufacturing a semiconductor device including an electrode on a nitride III-V compound semiconductor layer containing at least Ga, comprising:

the electrode being made by stacking at least an alloy of Ga and at least one kind of element selected from the group consisting of Pt, Ag, Pd, Mg, Hf, Al, Cr, Ti, Mo, W, Zr, Si and Ge on the nitride III-V compound semiconductor layer.

According to the 35th aspect of the invention, there is provided a method for manufacturing a semiconductor device including an electrode on a nitride III-V compound semiconductor layer containing at least Ga, comprising:

the electrode being made by first stacking at least an alloy of Ga and at least one kind of element selected from the group consisting of Pt, Ag, Pd, Mg, Hf, Al, Cr, Ti, Mo, W, Zr, Si and Ge on the nitride III-V compound semiconductor layer, and then annealing it at a temperature not lower than a temperature required for making the alloy.

According to the 36th aspect of the invention, there is provided a method for manufacturing a semiconductor device including an electrode on a nitride III-V compound semiconductor layer containing at least Ga, comprising:

the electrode being made by stacking an alloy of Ga and at least one kind of element selected from the group consisting of Pt, Ag, Pd, Mg, Hf, Al, Cr, Ti, Mo, W, Zr, Si and Ge on the nitride III-V compound semiconductor layer heated to a temperature not lower than a temperature required for making the alloy.

According to the 37th aspect of the invention, there is provided a method for manufacturing a semiconductor device including an electrode on a nitride III-V compound semiconductor layer containing at least Ga, comprising:

the electrode being made by first stacking Ga or a first compound containing Ga, and at least one kind of element selected from the group consisting of Pt, Ag, Pd, Mg, Hf, Al, Cr, Ti, Mo, W, Zr, Si and Ge or a second compound containing the at least one kind of element on the nitride III-V compound semiconductor layer, and then annealing it at a temperature not lower than a temperature required for making an alloy of Ga and the at least one kind of element.

According to the 38th aspect of the invention, there is provided a method for manufacturing a semiconductor device including an electrode on a nitride III-V compound semiconductor layer containing at least Ga, comprising:

the electrode being made by stacking Ga or a first compound containing Ga, and at least one kind of element selected from the group consisting of Pt, Ag, Pd, Mg, Hf, Al, Cr, Ti, Mo, W, Zr, Si and Ge or a second compound containing the at least one kind of element on the nitride III-V compound semiconductor layer heated to a temperature required for making an alloy of Ga and the at least one kind of element.

In the 21st to 38th aspects of the invention, examples of usable alloys of Ga are listed below.

| Groups of Alloys | Examples |
|---|---|
| Ga—Pt | GaPt₂ Ga₃Pt₅ Ga₂Pt |
| Ga—Ag | Ga_{0.28}Ag_{0.72} Ga_{0.5}Ag_{1.5} |
| Ga—Pd | Ga₅Pd Ga₂Pd₅ |
| Ga—Mg | Ga₅Mg₂ Ga₂Mg GaMg₂ |
| Ga—Hf | GaHf₂ GaHf Ga₂Hf |
| Ga—Cr | Ga₄Cr₃ GaCr₃ |
| Ga—Ti | Ga₅Ti₃ GaTi₃ Ga₄Ti₅ Ga₃Ti₂ |
| Ga—Mo | Ga₃₁Mo₆ GaMo₃ |
| Ga—Zr | GaZr₂ Ga₂Zr₃ Ga₂Zr Ga₃Zr₅ |

In the 21st through 38th aspects of the invention, Pt, Ag, Pd, Mg, Hf and Al are suitable as materials of the p-side electrode, among Pt, Ag, Pd, Mg, Hf, Al, Cr, Ti, Mo, W, Zr, Si and Ge. Especially, considering that Mg is a p-type impurity of nitride III-V compound semiconductors, the use of Mg as the material of the p-side electrode is advantageous in reducing the ohmic contact resistance because Mg is doped into the nitride III-V compound semiconductor layer along the electrode-semiconductor interface in the process of making the p-side electrode on the p-type nitride III-V compound semiconductor layer. On the other hand, suitable materials of the n-side electrode are Al, Ti, Mo, W, Zr, Si, Ge, Cr, Pt and Ag, for example.

In the 21st through 38th aspects of the invention, a metal for reducing the resistance of the electrode, which may be Au, for example, is typically provided to overlie. In this case, Pt is preferably stacked as a base layer of Au in order to prevent interaction of the underlying GaNi alloys with overlying Au, for example.

In the present invention, the nitride III-V compound semiconductor layer contains at least Ga as its group III element, and may additionally contain at least one kind of element selected from the group consisting of In, Al and B. The nitride III-V compound semiconductor layer contains at least N as its group V element, and may additionally contain As or P. More specifically, the nitride III-V compound semiconductor layer is made of, for example, GaN, AlGaN, GaInN or AlGaInN. The nitride III-V compound semiconductor layer is most typically of the p-type, but may be of the n-type.

In the present invention, usable as the method for making electrode materials are vacuum evaporation, sputtering and various kinds of chemical vapor deposition (CVD). For annealing or heating the nitride III-V compound semiconductor layer, various kinds of processes such as ordinary furnace annealing, flash lump annealing and laser annealing can be used.

In the present invention, the semiconductor device may be any type of device as far as it includes electrodes formed on a nitride III-V compound semiconductor layer containing at least Ga. For example, it may be a light emitting element like semiconductor laser or light emitting diode, or an electron mobility element like GaN-based FET.

According to the first to twentieth aspects of the invention having the above-summarized constructions, since at least a part of the portion of the electrode in contact with the nitride III-V compound semiconductor layer is made of a γ-GaNi alloy or γ′-GaNi alloy, the γ-GaNi alloy or γ′-GaNi alloy makes continuous bonding between the nitride III-V compound semiconductor layer and the electrode. Therefore, the ohmic contact resistance of the electrode can be reduced. Also, adhesion of the electrode to the nitride III-V compound semiconductor layer can be improved. Additionally, by intentionally making the γ-GaNi alloy or γ′-GaNi alloy along the electrode-semiconductor interface, it is possible to stably realize a good ohmic contact property in which the electrode-semiconductor interface is stable and prevents fluctuation of the ohmic contact property. Furthermore, by depositing a metal like Au as an overlying material via Pt on the γ-GaNi alloy, γ′-GaNi alloy, or on a material for making the alloy, the resistance of the electrode can be reduced, and undesired interaction can by prevented by the Pt layer.

According to the 21st through 38th aspects of the invention having the above-summarized constructions, since at least a part of the portion of the electrode in contact with the nitride III-V compound semiconductor layer is made of an alloy of Ga and at least one kind of element selected from the group consisting of Pt, Ag, Pd, Mg, Hf, Al, Cr, Ti, Mo, W, Zr, Si and Ge, the alloy makes continuous bonding between the nitride III-V compound semiconductor layer and the electrode. Therefore, the ohmic contact resistance of the electrode can be reduced. Also, adhesion of the electrode to the nitride III-V compound semiconductor layer can be improved. Additionally, by intentionally making the alloy of Ga and at least one kind of element selected from the group consisting of Pt, Ag, Pd, Mg, Hf, Al, Cr, Ti, Mo, W, Zr, Si and Ge along the electrode-semiconductor interface, it is possible to stably realize a good ohmic contact property in which the electrode-semiconductor interface is stable and prevents fluctuation of the ohmic contact property. Furthermore, by depositing a metal like Au as an overlying material via Pt on the alloy of Ga and at least one kind of element selected from the group consisting of Pt, Ag, Pd, Mg, Hf, Al, Cr, Ti, Mo, W, Zr, Si and Ge, or on a material for making the alloy, the resistance of the electrode can be reduced, and undesired interaction can by prevented by the Pt layer.

The above, and other, objects, features and advantage of the present invention will become readily apparent from the following detailed description thereof which is to be read in connection with the accompanying drawings.

### BRIEF DESCRIPTION OF THE DRAWINGS

FIG. 1 is a perspective view of a GaN-based semiconductor laser according to the first embodiment of the invention;

FIG. 2 is a cross-sectional view of a part of the semiconductor laser according to the first embodiment of the invention to show its p-side electrode contact portion in an enlarged scale; and

FIG. 3 is a cross-sectional view of a part of the semiconductor laser according to the first embodiment of the invention to show its p-side electrode contact portion in an enlarged scale.

### DETAILED DESCRIPTION OF THE PREFERRED EMBODIMENTS

Explained below are embodiments of the invention with reference to the drawings. In all of the drawings showing the embodiments, common reference numerals are attached to the same or equivalent parts or elements.

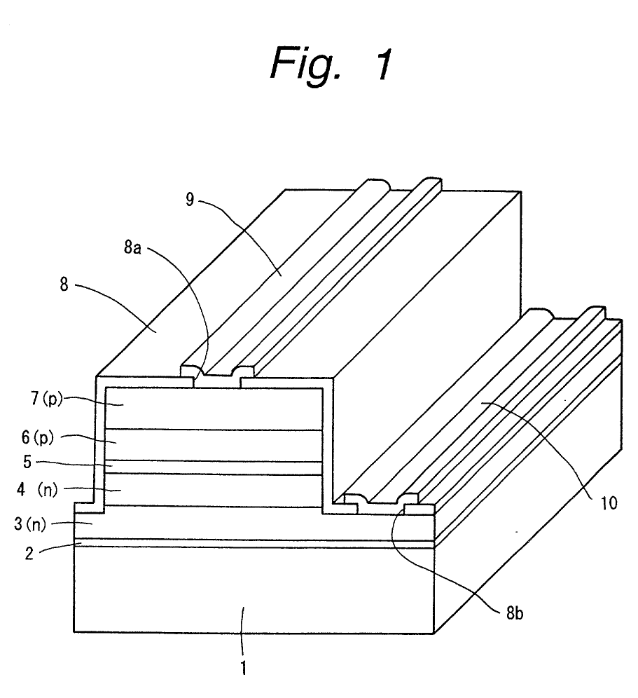

FIG. 1 shows a GaN semiconductor laser according to the first embodiment of the invention. As shown in FIG. 1, in the GaN semiconductor laser, an n-type GaN contact layer 3, n-type AlₓGa₁₋ₓN cladding layer 4, active layer 5 made of low-impurity-concentrated or undoped Ga_{1-y}In_{y}N, for example, p-type Al₂Ga_{1-z}N cladding layer 6 and p-type GaN contact layer 7 which are sequentially stacked on a c-plane sapphire substrate 1 via a GaN buffer layer 2.

The n-type GaN contact layer 3 and the n-type AlₓGa₁₋ₓN cladding layer 4 are doped with Si, for example, as their n-type impurity. The p-type Al_{z}Ga_{1-z}N cladding layer 6 and the p-type GaN contact layer 7 are doped with Mg, for example, as their p-type impurity. Examples of their thicknesses are 30 nm of the GaN buffer layer 2, 3 μm of the n-type GaN contact layer, 0.5 μm of the n-type AlₓGa₁₋ₓN layer 4, 0.05 μm of the active layer, 0.5 μm of the p-type Al_{z}Ga_{1-z}N cladding layer 6, and 1 μm of the p-type GaN contact layer 7.

The upper-lying part of the n-type GaN contact layer 3, n-type AlₓGa₁₋ₓN cladding layer 4, active layer 5, p-type Al_{z}Ga_{1-z}N cladding layer 6 and p-type GaN contact layer 7 make a stripe configuration extending in one direction. An insulating film 8, such as SiO₂ film, is provided to cover surfaces of the stripe portion and the remainder portion. The insulating film 8 has formed stripe-shaped apertures 8a and 8b above the p-type GaN contact layer 7 and above the n-type GaN contact layer 3. These apertures 8a and 8b may be 5 μm wide, for example. Through the aperture 8a, the p-side electrode 9 gets into ohmic contact with the p-type GaN contact layer 7. Through the aperture 8b, the n-side electrode 10 gets into ohmic contact with the n-type GaN contact layer 3. The n-side electrode 10 may have a Au/Al/Ti structure, for example.

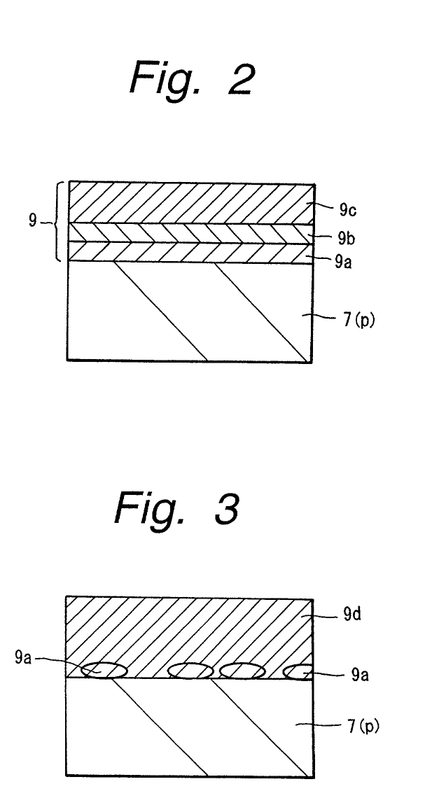

The contact portion of the p-side electrode 9 with the p-type GaN contact layer 7 is shown in FIG. 2 in an enlarged scale. As shown in FIG. 2, the p-side electrode 9 includes a γ-GaNi alloy layer 9a inconstant with the p-type GaN contact layer 7, and a Pt film 9b and a Au film 9c sequentially stacked thereon. At least a part of the γ-GaNi alloy layer 9a is epitaxially grown from the underlying p-type GaN contact layer 7, and their relative orientations are γ-GaNi{0-100}∥GaN{1000} and γ-GaNi{0001}∥GaN{0-111}. The p-side electrode 9 and the p-type GaN contact layer 7 are continuously bonded by the γ-GaNi alloy layer 9a. Thickness of the γ-GaNi alloy layer may be 3 through 50 nm, more specifically, 10 nm, for example. Thickness of the Pt film 9b is 100 nm, for example, and thickness of the Au film 9c is 200 nm, for example.

Next explained is a method for manufacturing the GaN semiconductor laser according to the first embodiment, having the above-explained construction.

First of all, in a reaction vessel of a metal organic chemical vapor deposition (MOCVD) apparatus, for example, the c-plane sapphire substrate 1 is heated to 1050° C., for example, in an atmosphere containing nitrogen (N₂) for thermal cleaning of its surface. Next, at a low temperature around 520° C., for example, the GaN buffer layer 2 is grown on the c-plane sapphire substrate 1 by MOCVD. After that, the n-type GaN contact layer 3, n-type AlₓGa₁₋ₓN cladding layer 4, active layer 5 made of low-impurity-concentrated or undoped Ga_{1-y}In_{y}N, for example, p-type Al_{z}Ga_{1-z}N cladding layer 6 and p-type GaN contact layer 7 are sequentially grown on the GaN buffer layer 2 by MOCVD. The n-type GaN contact layer 3, n-type AlₓGa₁₋ₓN cladding layer 4, p-type Al_{z}Ga_{1-z}N cladding layer 6 and p-type GaN contact layer 7 are grown at a temperature around 1000° C., for example, whereas the active layer 5 made of Ga_{1-y}In_{y}N is grown at a lower temperature around 700 through 850° C., for example, to prevent decomposition of InN. Source materials used for growth of these GaN semiconductor layers are, for example, trimethyl gallium (TMG) as the source material of a group III element Ga, trimethyl aluminum (TMA) as the source material of a group III element Al, trimethyl indium (TMI) as the source material of a group III element In, and ammonium (NH₃) as the source material of a group V element N. Used as the carrier gas is a mixed gas of hydrogen (H₂) and nitrogen (N₂), for example. Dopants used here are mono silane (SiH₄), for example, as the n-type dopant, and methylcyclopentadienile magnesium (MCp)₂Mg), for example, as the p-type dopant.

Then, a stripe-shaped resist pattern (not shown) is formed on the p-type GaN contact layer 7 by lithography. Using the resist pattern as a mask, the n-type GaN contact layer 3 is etched to its certain depth by dry etching or wet etching, such as reactive ion etching (RIE), for example. As a result, the upper-lying part of the n-type GaN contact layer 3, n-type AlₓGa₁₋ₓN cladding layer 4, active layer 5, p-type Al_{z}Ga_{1-z}N cladding layer 6 and p-type GaN contact layer 7 are patterned into a stripe.

Then, the resist pattern used as the etching mask is removed. Thereafter, the insulating film 8 is formed on the entire surface by CVD or sputtering, for example. Another resist pattern (not shown) is next formed to cover the surface excluding the region for the n-side electrode by lithography. Using this resist pattern as a mask, the insulating film 8 is etched to make the aperture 8b. After that, the resist pattern is removed.

Thereafter, a Ti film, Al film and Au film are sequentially formed by vacuum evaporation or sputtering, for example, and these Ti film, Al film and Au film are etched and patterned into a predetermined configuration. As a result, the n-side electrode 10 with the Au/Al/Ti structure is made on the n-type GaN contact layer 3 in the portion of the aperture 8b of the insulating film 8.

Thereafter, annealing is conducted at 800° C. in a N₂ atmosphere, for example, to electrically activate the p-type impurity doped into the p-type Al_{z}Ga_{1-z}N cladding layer 6 and the p-type GaN contact layer 7 and to alloy the n-side electrode 10.

After that, another resist pattern (not shown) is formed to cover the surface of the region excluding the region for the p-side electrode by lithography. Then, using the resist pattern as a mask, the insulating film 8 is etched to make the aperture 8a.

Subsequently, the γ-GaNi alloy layer 9a, Pt film 9b and Au film 9c are sequentially formed on the entire surface by vacuum evaporation or sputtering, for example, and they are etched and patterned into a predetermined configuration. Then, in a N₂ gas atmosphere, for example, annealing is conducted at a temperature not lower than 680° C. required for making the γ-GaNi alloy, namely at 680 through 730° C., for example. As a result, the p-side electrode 9 having the structure shown in FIG. 2 is formed to be continuously bonded to the p-type GaN contact layer 7 by the γ-GaNi alloy layer 9a, and a low-resistance ohmic contact is obtained.

After that, the c-plane sapphire substrate 1 having formed the laser structure as explained above is cleaved into bars. As a result, the n-type GaN contact layer 3, n-type AlₓGa₁₋ₓN cladding layer 4, active layer 5, p-type Al_{z}Ga_{1-z}N cladding layer 6 and p-type GaN contact layer 7 grown on the c-plane sapphire substrate 1 are cleaved together. The cleavage is practically progressed as explained below. That is, mark-off line or grooves having a wedge-shaped, V-shaped or U-shaped cross-sectional configuration with a non-flat bottom are formed on a part of the entire bottom surface of the c-plane sapphire substrate 1 to extend linearly in the cavity lengthwise direction in parallel with each other with a distance corresponding to the cavity length. These mark-off lines or grooves may be made by using a scriber or dicing device, for example. After that, while applying to the c-plane sapphire substrate 1 a tensile force parallel to the surface and vertical to the mark-off lines or grooves on the bottom surface of the sapphire substrate 1, a stress is concentrated to the deepest portion of these mark-off lines or grooves by applying an external force to arcuately bend the sapphire substrate 1, producing a thermal stress or applying an ultrasonic wave. As a result, the c-plane sapphire substrate 1 is cleaved from the mark-off lines or grooves on the bottom surface thereof, and the GaN semiconductor layers on the c-plane sapphire substrate 1 are cleaved as well.

After that, each cleaved bar of the c-plane sapphire substrate 1 and the GaN semiconductor layers thereon is cut and divided into chips along the direction vertical of the cavity lengthwise direction to form laser chips. Division into chips may be done by cleaving each bar in the same manner as cleavage into bars, for example. As a result, the intended GaN semiconductor laser is completed.

As explained above, according to the invention, the γ-GaNi alloy layer 9a forming a part of the p-side electrode 9 in contact with the p-type GaN contact layer 7 functions to continuously bond the p-side electrode 9 and the p-type GaN contact layer 7. Therefore, the ohmic contact resistance of the p-side electrode 9 is significantly reduced, and realization of a GaN semiconductor laser with a low drive voltage and low power consumption is promised. Additionally, since the p-side electrode 9 is improved in adhesion, it does not peel off easily, and the reliability of the GaN semiconductor laser can be improved.

Next explained is the second embodiment of the invention. In the second embodiment, the p-side electrode 9 is made by a method different from that of the first embodiment. That is, in the second embodiment, after the aperture 8a is formed in the insulating film 8, a Ni film, Pt film and Au film are sequentially deposited on the entire surface by vacuum evaporation of sputtering, for example, and they are patterned into a predetermined configuration by etching. After that, in a N₂ gas atmosphere, for example, annealing is conducted at a temperature not lower than 680° C. required for making the γ-GaNi alloy, namely, at 680 through 730° C., for example. As a result, the γ-GaNi alloy layer 9c is formed by interaction of the Ni film and the p-type GaN contact layer 7, and the p-side electrode 9 with the structure shown in FIG. 2 is obtained. In the other respect, the second embodiment is the same as the first embodiment, and its explanation in these respects is omitted.

The second embodiment also promises the same advantages as those of the first embodiment.

Next explained is a GaN semiconductor laser according to the third embodiment.

In the GaN semiconductor laser according to the third embodiment, a part of the p-side electrode 9 in contact with the p-type GaN contact layer 7 is partly made of the γ-GaNi alloy layer 9a, and the remainder part is made of Au/Pt 9d. In this case, the p-side electrode 9 and the p-type GaN contact layer 7 are continuously bonded by the γ-GaNi alloy layer 9a. In the other respects, the third embodiment is the same as the GaN semiconductor laser according to the first embodiment, and its explanation in these respects is omitted.

The third embodiment also promises the same advantages as those of the first embodiment.

Next explained is the fourth embodiment of the invention. In the fourth embodiment, the p-side electrode 9 is made by a method different from that of the first embodiment. That is, in the fourth embodiment, after the aperture 8a is made in the insulating film 8, a Ni film is deposited on the entire surface by vacuum evaporation or sputtering, for example. After that, in a N₂ gas atmosphere, for example, annealing is conducted at a temperature not lower than 680° C. required for making the γ-GaNi alloy, namely, at 680 through 730° C., for example. As a result, the γ-GaNi alloy layer 9a is formed by interaction of the Ni film and the p-type GaN contact layer 7. Thereafter, a Pt film and a Au film are sequentially deposited on the entire surface by vacuum evaporation or sputtering, for example, and these Pt film and Au film are patterned into a predetermined configuration together with the underlying γ-GaNi alloy layer 9a by etching. As a result, the p-side electrode 9 with the structure as shown in FIG. 2 is obtained. In the other respect, the fourth embodiment is the same as the first embodiment, and its explanation in these respects is omitted.

The fourth embodiment also promises the same advantages as those of the first embodiment.

Next explained is the fifth embodiment of the invention. In the fifth embodiment, the p-side electrode 9 is made by a method different from that of the first embodiment. That is, in the fifth embodiment, after the aperture 8a is made in the insulating film 8, the substrate temperature is fixed to a temperature not lower than 680° C., namely, at 680 through 730° C., for example, and a Ni film, Pt film and Au film are sequentially deposited on the entire surface by vacuum evaporation or sputtering, for example. As a result, the γ-GaNi alloy layer 9a is formed by interaction between the Ni film and the p-type GaN contact layer 7, and the p-side electrode with the structure as shown in FIG. 2 is obtained. In the other respects, the fifth embodiment if the same as the first embodiment, and its explanation in these respects is omitted.

The fifth embodiment also promises the same advantages as those of the first embodiment.

Next explained is the sixth embodiment of the invention. In the sixth embodiment, the p-side electrode 9 is made by a method different from that of the first embodiment. That is, in the fifth embodiment, after the aperture 8a is made in the insulating film 8, the substrate temperature is fixed to a temperature not lower than 680° C., namely, at 680 through 730° C., for example, and a Ni film is sequentially deposited on the entire surface by vacuum evaporation or sputtering, for example. As a result, the γ-GaNi alloy layer 9a is formed by interaction between the Ni film and the p-type GaN contact layer 7. After that, a Pt film and a Au film are sequentially deposited on the entire surface by vacuum evaporation or sputtering, for example, and these Pt film and Au film are patterned by etching into a predetermined configuration together with the underlying γ-GaNi alloy layer 9a. As a result, the p-side electrode 9 with the structure as shown in FIG. 2 is obtained. In the other respect, the sixth embodiment is the same as the first embodiment, and its explanation in these respects is omitted.

The sixth embodiment also promises the same advantages as those of the first embodiment.

Having described specific preferred embodiments of the present invention with reference to the accompanying drawings, it is to be understood that the invention is not limited to those precise embodiments, and that various changes and modifications may be effected therein by one skilled in the art without departing from the scope or the spirit of the invention as defined in the appended claims.

For example, the numerical values, structures, source materials, and processes, for example, used in the first through six embodiments are not but examples, and any other appropriate numerical values, structures, source materials and processes may be employed.

More specifically, in the first to sixth embodiments, MOCVD is employed for growth of the GaN semiconductor layers. However, molecular beam epitaxy, for example, may be used for growth of the GaN semiconductor layers.

Moreover, in the first to sixth embodiments, n-side GaN semiconductor layers are formed on the part nearer to the c-plane sapphire substrate 1. However, it is possible to make p-type GaN semiconductor layers nearer to the c-plane sapphire substrate 1 and make the p-side electrode according to any of the first to sixth embodiments on the p-type GaN contact layer among these p-type GaN semiconductor layers.

Furthermore, the first to sixth embodiments have been explained as applying the invention to GaN semiconductor lasers of a DH (Double Heterostructure). However, the invention is applicable also to GaN semiconductor lasers with a SCH (Separate Confinement Heterostructure) structure. Additionally, the active layer 5 may be one with a multi quantum well structure. Further, any laser structure may be employed from various types of semiconductor lasers of a ridge-guided type, internal current blocking type, structural substrate type, longitudinal mode control type (Distributed Feedback (DFB) type or Distributed Bragg Reflector (DBR) type), which can realize a gain-guided or index-guided semiconductor laser. The invention is also applicable to GaN light emitting diodes and electron transport devices like GaN FET.

As explained above, according to the invention, since at least a part of an electrode in contact with a nitride III-V compound semiconductor layer is made of a γ-GaNi alloy or a γ′-GaNi alloy, the electrode can be reduced in ohmic contact resistance and improved adhesion relative to the nitride III-V compound semiconductor layer, and a high reliability is obtained.

Additionally, according to the invention, since at least a part of an electrode in contact with a nitride III-V compound semiconductor layer is made of an alloy of Ga and at least one kind of element selected from the group consisting of Pt, Ag, Pd, Mg, Hf, Al, Cr, Ti, Mo, W, Zr, Si and Ge, the electrode can be reduced in ohmic contact resistance and improved adhesion relative to the nitride III-V compound semiconductor layer, and a high reliability is obtained.

What is claimed is:

1. An electrode on a nitride III-V compound semiconductor layer containing at least Ga, comprising:
at least a part of said electrode in contact with said nitride III-V compound semiconductor layer being made of a γ-GaNi alloy or a γ′-GaNi alloy.

2. An electrode on a nitride III-V compound semiconductor layer containing at least Ga, characterized in:
being made by first stacking at least a γ-GaNi alloy or a γ′-GaNi alloy on said nitride III-V compound semiconductor layer, and next annealing it at a temperature not lower than 680° C.

3. The electrode according to claim 2 characterized in being made by sequentially stacking said γ-GaNi alloy or said γ′-GaNi alloy, Pt and Au on said nitride III-V compound semiconductor layer, and next annealing them at a temperature not lower than 680° C.

4. An electrode on a nitride III-V compound semiconductor layer containing at least Ga, characterized in:
being made by stacking at least a γ-GaNi alloy or a γ′-GaNi alloy on said nitride III-V compound semiconductor layer heated to a temperature not lower than 680° C.

5. The electrode according to claim 4 characterized in being made by sequentially stacking said γ-GaNi alloy or said γ′-GaNi alloy, Pt and Au on said nitride III-V compound semiconductor layer heated to a temperature not lower than 680° C.

6. An electrode on a nitride III-V compound semiconductor layer containing at least Ga, characterized in:
being made by first stacking at least Ga, or a first compound containing Ga, and Ni, or a second compound containing Ni, on said nitride III-V compound semiconductor layer, and next annealing them at a temperature not lower than 680° C.

7. An electrode on a nitride III-V compound semiconductor layer containing at least Ga, characterized in:
being made by first sequentially stacking Ni, Pt and Au, and next annealing them at a temperature not lower than 680° C.

8. A method for making an electrode on a nitride III-V compound semiconductor layer containing at least Ga, comprising:
stacking at least a γ-GaNi alloy or a γ′-GaNi alloy on said nitride III-V compound semiconductor layer.

9. A method for making an electrode on a nitride III-V compound semiconductor layer containing at least Ga, comprising:
first stacking at least a γ-GaNi alloy or a γ′-GaNi alloy on said nitride III-V compound semiconductor layer, and next annealing it at a temperature not lower than 680° C.

10. The method for making an electrode according to claim 9 wherein said γ-GaNi alloy or said γ′-GaNi alloy is sequentially staked on said nitride III-V compound semiconductor layer, and it is next annealed at a temperature not lower then 680° C.

11. A method for making an electrode on a nitride III-V compound semiconductor layer containing at least Ga, comprising:
stacking at least a γ-GaNi alloy or a γ′-GaNi alloy on said nitride III-V compound semiconductor layer heated to a temperature not lower than 680° C.

12. The method for making an electrode according to claim 11 wherein said γ-GaNi alloy or said γ′-GaNi alloy, Pt and Au are sequentially stacked on said nitride III-V compound semiconductor layer heated to a temperature not lower than 680° C.

13. A method for making an electrode on a nitride III-V compound semiconductor layer containing at least Ga, comprising:
first stacking at least Ga, or a first compound containing Ga, and Ni, or a second compound containing Ni, on said nitride III-V compound semiconductor layer, and next annealing them at a temperature not lower than 680° C.

14. A method for making an electrode on a nitride III-V compound semiconductor layer containing at least Ga, comprising:
first sequentially stacking Ni, Pt and Au, and next annealing them at a temperature not lower than 680° C.

15. A semiconductor device including an electrode on a nitride III-V compound semiconductor layer containing at least Ga, comprising:
at least a part of said electrode in contact with said nitride III-V compound semiconductor layer being made of a γ-GaNi alloy or a γ′-GaNi alloy.

16. A semiconductor device including an electrode on a nitride III-V compound semiconductor layer containing at least Ga, comprising:
said electrode being made by first stacking at least a γ-GaNi alloy or a γ′-GaNi alloy on said nitride III-V compound semiconductor layer, and next annealing it at a temperature not lower than 680° C.

17. The semiconductor device according to claim 16 wherein said electrode is made by sequentially stacking said γ-GaNi alloy or said γ′-GaNi alloy, Pt and Au on said nitride III-V compound semiconductor layer, and next annealing them at a temperature not lower than 680° C.

18. A semiconductor device including an electrode on a nitride III-V compound semiconductor layer containing at least Ga, comprising:
said electrode being made by stacking at least a γ-GaNi alloy or a γ′-GaNi alloy on said nitride III-V compound semiconductor layer heated to a temperature not lower than 680° C.

19. The semiconductor device according to claim 4 wherein said electrode is made by sequentially stacking said γ-GaNi alloy or said γ′-GaNi alloy, Pt and Au on said nitride III-V compound semiconductor layer heated to a temperature not lower than 680° C.

20. A semiconductor device including an electrode on a nitride III-V compound semiconductor layer containing at least Ga, comprising:
said electrode being made by first stacking at least Ga, or a first compound containing Ga, and Ni, or a second compound containing Ni, on said nitride III-V compound semiconductor layer, and next annealing them at a temperature not lower than 680° C.

21. A semiconductor device including an electrode on a nitride III-V compound semiconductor layer containing at least Ga, comprising:
said electrode being made by first sequentially stacking Ni, Pt and Au, and next annealing them at a temperature not lower than 680° C.

22. A method for manufacturing a semiconductor device including an electrode on a nitride III-V compound semiconductor layer containing at least Ga, comprising:
said electrode being made by stacking at least a γ-GaNi alloy or a γ′-GaNi alloy on said nitride III-V compound semiconductor layer.

23. A method for manufacturing a semiconductor device including an electrode on a nitride III-V compound semiconductor layer containing at least Ga, comprising:
said electrode being made by first stacking at least a γ-GaNi alloy or a γ′-GaNi alloy on said nitride III-V compound semiconductor layer, and next annealing it at a temperature not lower than 680° C.

24. The method for manufacturing a semiconductor device according to claim 23 wherein said γ-GaNi alloy or said γ′-GaNi alloy is sequentially staked on said nitride III-V compound semiconductor layer, and it is next annealed at a temperature not lower then 680° C.

25. A method for manufacturing a semiconductor device including an electrode on a nitride III-V compound semiconductor layer containing at least Ga, comprising:
said electrode being made by stacking at least a γ-GaNi alloy or a γ′-GaNi alloy on said nitride III-V compound semiconductor layer heated to a temperature not lower than 680° C.

26. The method for manufacturing a semiconductor device according to claim 25 wherein said electrode is made by sequentially stacking said γ-GaNi alloy or said γ′-GaNi alloy, Pt and Au on said nitride III-V compound semiconductor layer heated to a temperature not lower than 680° C.

27. A method for manufacturing a semiconductor device including an electrode on a nitride III-V compound semiconductor layer containing at least Ga, comprising:
said electrode being made by first stacking at least Ga, or a first compound containing Ga, and Ni, or a second compound containing Ni, on said nitride III-V compound semiconductor layer, and next annealing them at a temperature not lower than 680° C.

28. A method for manufacturing a semiconductor device including an electrode on a nitride III-V compound semiconductor layer containing at least Ga, comprising:
said electrode being made by first sequentially stacking Ni, Pt and Au, and next annealing them at a temperature not lower than 680° C.

29. An electrode on a nitride III-V compound semiconductor layer containing at least Ga, comprising:
at least a part of said electrode in contact with said nitride III-V compound semiconductor layer being made of an alloy of Ga and at least one kind of element selected from the group consisting of Pt, Ag, Pd, Mg, Hf, Al, Cr, Ti, Mo, W, Zr, Si and Ge.

30. An electrode on a nitride III-V compound semiconductor layer containing at least Ga, characterized in:
being made by first stacking an alloy of Ga and at least one kind of element selected from the group consisting of Pt, Ag, Pd, Mg, Hf, Al, Cr, Ti, Mo, W, Zr, Si and Ge, and next annealing it at a temperature not lower than a temperature required for making said alloy.

31. An electrode on a nitride III-V compound semiconductor layer containing at least Ga, characterized in:
being made by sequentially stacking an alloy of Ga and at least one kind of element selected from the group consisting of Pt, Ag, Pd, Mg, Hf, Al, Cr, Ti, Mo, W, Zr, Si and Ge on said nitride III-V compound semiconductor layer heated to a temperature not lower than a temperature required for making said alloy.

32. An electrode on a nitride III-V compound semiconductor layer containing at least Ga, characterized in:
being made by stacking at least Ga or a first compound containing Ga, and at least one kind of element selected from the group consisting of Pt, Ag, Pd, Mg, Hf, Al, Cr, Ti, Mo, W, Zr, Si and Ge or a second compound containing said at least one kind of element on said nitride III-V compound semiconductor layer, and next annealing them at a temperature not lower than a temperature required for making an alloy of Ga and said at least one kind of element.

33. A method for making an electrode on a nitride III-V compound semiconductor layer containing at least Ga, comprising:
stacking at least an alloy of Ga and at least one kind of element selected from the group consisting of Pt, Ag, Pd, Mg, Hf, Al, Cr, Ti, Mo, W, Zr, Si and Ge.

34. A method for making an electrode on a nitride III-V compound semiconductor layer containing at least Ga, comprising:
first stacking at least an alloy of Ga and at least one kind of element selected from the group consisting of Pt, Ag, Pd, Mg, Hf, Al, Cr, Ti, Mo, W, Zr, Si and Ge, and next annealing it at a temperature not lower than a temperature required for making said alloy.

35. A method for making an electrode on a nitride III-V compound semiconductor layer containing at least Ga, comprising:
sequentially stacking an alloy of Ga and at least one kind of element selected from the group consisting of Pt, Ag, Pd, Mg, Hf, Al, Cr, Ti, Mo, W, Zr, Si and Ge on said nitride III-V compound semiconductor layer heated to a temperature not lower than a temperature required for making said alloy.

36. A method for making an electrode on a nitride III-V compound semiconductor layer containing at least Ga, comprising:
stacking at least Ga or a first compound containing Ga, and at least one kind of element selected from the group consisting of Pt, Ag, Pd, Mg, Hf, Al, Cr, Ti, Mo, W, Zr, Si and Ge or a second compound containing said at least one kind of element on said nitride III-V compound semiconductor layer, and next annealing them at a temperature not lower than a temperature required for making an alloy of Ga and said at least one kind of element.

37. A method for making an electrode on a nitride III-V compound semiconductor layer containing at least Ga, comprising:
stacking at least Ga or a first compound containing Ga, and at least one kind of element selected from the group consisting of Pt, Ag, Pd, Mg, Hf, Al, Cr, Ti, Mo, W, Zr, Si and Ge or a second compound containing said at least one kind of element on said nitride III-V compound semiconductor layer heated to a temperature not lower than a temperature required for making an alloy of Ga and said at least one kind of element.

38. A semiconductor device including an electrode on a nitride III-V compound semiconductor layer containing at least Ga, comprising:
at least a part of said electrode in contact with said nitride III-V compound semiconductor layer being made of an alloy of Ga and at least one kind of element selected from the group consisting of Pt, Ag, Pd, Mg, Hf, Al, Cr, Ti, Mo, W, Zr, Si and Ge.

39. A semiconductor device including an electrode on a nitride III-V compound semiconductor layer containing at least Ga, comprising:
said electrode being made by first stacking at least an alloy of Ga and at least one kind of element selected from the group consisting of Pt, Ag, Pd, Mg, Hf, Al, Cr, Ti, Mo, W, Zr, Si and Ge, and then annealing it at a temperature not lower than a temperature required for making an alloy of Ga and said at least one kind of element.

40. A semiconductor device including an electrode on a nitride III-V compound semiconductor layer containing at least Ga, comprising:
said electrode being made by stacking at least an alloy of Ga and at least one kind of element selected from the group consisting of Pt, Ag, Pd, Mg, Hf, Al, Cr, Ti, Mo, W, Zr, Si and Ge on said nitride III-V compound semiconductor layer heated to a temperature not lower than a temperature required for making said alloy.

41. A semiconductor device including an electrode on a nitride III-V compound semiconductor layer containing at least Ga, comprising:
stacking at least Ga or a first compound containing Ga, and at least one kind of element selected from the group consisting of Pt, Ag, Pd, Mg, Hf, Al, Cr, Ti, Mo, W, Zr, Si and Ge or a second compound containing said at least one kind of element on said nitride III-V compound semiconductor layer, and then annealing it at a temperature not lower than a temperature required for making an alloy of Ga and said at least one kind of element.

42. A method for manufacturing a semiconductor device including an electrode on a nitride III-V compound semiconductor layer containing at least Ga, comprising:
said electrode being made by stacking at least an alloy of Ga and at least one kind of element selected from the group consisting of Pt, Ag, Pd, Mg, Hf, Al, Cr, Ti, Mo, W, Zr, Si and Ge on said nitride III-V compound semiconductor layer.

43. A method for manufacturing a semiconductor device including an electrode on a nitride III-V compound semiconductor layer containing at least Ga, comprising:
said electrode being made by first stacking at least an alloy of Ga and at least one kind of element selected from the group consisting of Pt, Ag, Pd, Mg, Hf, Al, Cr, Ti, Mo, W, Zr, Si and Ge on said nitride III-V compound semiconductor layer, and then annealing it at a temperature not lower than a temperature required for making said alloy.

44. A method for manufacturing a semiconductor device including an electrode on a nitride III-V compound semiconductor layer containing at least Ga, comprising:
said electrode being made by stacking an alloy of Ga and at least one kind of element selected from the group consisting of Pt, Ag, Pd, Mg, Hf, Al, Cr, Ti, Mo, W, Zr, Si and Ge on said nitride III-V compound semiconductor layer heated to a temperature not lower than a temperature required for making said alloy.

45. A method for manufacturing a semiconductor device including an electrode on a nitride III-V compound semiconductor layer containing at least Ga, comprising:
said electrode being made by first stacking Ga or a first compound containing Ga, and at least one kind of element selected from the group consisting of Pt, Ag, Pd, Mg, Hf, Al, Cr, Ti, Mo, W, Zr, Si and Ge or a second compound containing said at least one kind of element on said nitride III-V compound semiconductor layer, and then annealing it at a temperature not lower than a temperature required for making an alloy of Ga and said at least one kind of element.

46. A method for manufacturing a semiconductor device including an electrode on a nitride III-V compound semiconductor layer containing at least Ga, comprising:
said electrode being made by stacking Ga or a first compound containing Ga, and at least one kind of element selected from the group consisting of Pt, Ag, Pd, Mg, Hf, Al, Cr, Ti, Mo, W, Zr, Si and Ge or a second compound containing said at least one kind of element on said nitride III-V compound semiconductor layer heated to a temperature required for making an alloy of Ga and said at least one kind of element.
